(19) United States
(12) Patent Application Publication
(10) Pub. No.: US 2006/0119356 A1
(43) Pub. Date: Jun. 8, 2006

(54) Magnetoresistive layer system and sensor element with said layer system

(76) Inventors: Maik Rabe, Wannweil (DE); Henrik Siegle, Leonberg (DE)

Correspondence Address: KENYON & KENYON LLP, ONE BROADWAY, NEW YORK, NY, 10004, US

(21) Appl. No.: 10/537,955

(22) PCT Filed: Oct. 18, 2003
(86) PCT No.: PCT/DE03/03503

§ 371 Date: Dec. 13, 2005

(30) Foreign Application Priority Data
Dec. 17, 2002 (DE) 102 58 860.0

(51) Int. Cl. G01R 33/02

(52) U.S. Cl. 324/252

(57) ABSTRACT

A magneto-resistive layer system, in which a layer arrangement is provided in an environment of a magneto-resistive layer stack working on the basis of the GMR effect or the AMR effect, in particular the layer arrangement generating a resulting magnetic field that acts upon the magneto-resistive layer stack. The layer arrangement has a first magnetic layer and a second magnetic layer, which are separated from one another by a non-magnetic intermediate layer and are ferromagnetically exchange-coupled via the intermediate layer. Furthermore, a sensor element having such a layer system is provided, particularly for the detection of magnetic fields with respect to their strength and/or direction.

### BACKGROUND INFORMATION

Magneto-resistive layer systems or corresponding sensor elements to be used in automobiles, for instance, in which the working point is able to be shifted by auxiliary magnetic fields, are known from the related art. Known, in particular, is the generation of such an auxiliary magnetic field by mounted macroscopic hard magnets or by current-traversed field coils.

Besides that, in German Patent Application No. DE 101 28 135.8, a concept is discussed where, in the vicinity of a magneto-resistive layer stack, especially on or underneath the layer stack, a magnetically hard layer is deposited which couples into the actual sensitive layers of the layer stack, primarily because of its stray field. On the one hand, the highest possible coercivity is in the fore as target parameter and, on the other hand, the remanent magnetic field is in the fore as limiting parameter. However, in a vertical integration, such a magnetically hard layer also leads to an electrical short circuit of the adjacent sensitive layers of the magneto-resistive layer system, which restricts a desired GMR effect (“giant magneto-resistance”) or an AMR effect (“anisotropic magnetic resistance”) or restricts the sensitivity of the layer system with respect to an external magnetic field to be analyzed.

In German Patent Application No. DE 101 40 606.1, it is described that, depending on the thickness of the individual layers and their composition, two magnetic layers are able to couple the directions of their respective magnetizations in a ferromagnetic or anti-ferromagnetic manner via a non-magnetic intermediate layer.

It is an objective of the present invention to provide a magneto-resistive layer system having high sensitivity with respect to an external magnetic field, such sensitivity being temperature-independent at the same time, if possible.

### SUMMARY OF THE INVENTION

The magneto-resistive layer system according to the present invention and the sensor element having this layer system according to the present invention have the advantage that the temperature dependency of its sensitivity for detecting external magnetic fields with respect to strength and/or direction is only very slight or, preferably, virtually non-existent within a predefined temperature interval.

In known magneto-resistive sensor elements, which are configured on a GMR layer stack according to the principle of coupled multi-layers, for instance, the maximum sensitivity of the layer stack with respect to an external magnetic field or the magnetic force of this magnetic field, which is generally to be reached at room temperature, changes with the temperature. Moreover, its sensitivity also changes as a function of the bias magnetic field or auxiliary magnetic field generated within the layer stack via an integrated magnetically hard layer, for instance, so that it is indeed possible to set a working point of the magneto-resistive layer stack that is a function of the temperature and the intensity of the bias or auxiliary magnetic field. Overall, given a predefined bias magnetic field, this has the result that the working point of the sensor element shifts considerably as a function of the temperature, which is usually accompanied by a marked loss in sensitivity.

In contrast, in the magneto-resistive layer system according to the present invention, due to the special configuration of the layer arrangement which produces a resulting magnetic field acting on the magneto-resistive layer stack, the sensitivity of the magneto-resistive layer system does not change at all or changes only slightly as a function of the temperature, or the working point of the magneto-resistive layer system does not change either or changes only negligibly in a corresponding manner. It is especially advantageous here if the layer arrangement which generates the bias magnetic field has a temperature dependency of the generated resulting magnetic field that compensates the temperature dependency of the magneto-resistive layer stack in the magneto-resistive layer system to just such an extent that the working point of the layer stack will not be shifted and/or the sensitivity will remain unchanged.

In this respect, the layer arrangement in the magneto-resistive layer system according to the present invention, or in the sensor element produced thereby, exhibits a temperature progression of the resulting magnetic field that is adaptable to the temperature progression of the working point of the magneto-resistive layer stack; in contrast, magnetically hard materials, especially with high Curie temperatures, have an intrinsic temperature progression of the magnetization.

Thus, while in a pure, magnetically hard layer the bias stray magnetic field or auxiliary magnetic field produced above is always approximately proportional to the magnetization of the magnetically hard layer, the resulting magnetic field of the layer arrangement provided according to the present invention is advantageously determined by the temperature dependency of the intermediate layer exchange coupling.

For example, the stray-field coupling of the first magnetic layer and the second magnetic layers, which are ferromagnetically exchange-coupled via the intermediate layer, is oppositely directed in the provided ferromagnetic intermediate-layer coupling, i.e., anti-ferromagnetic in this sense. If the ferromagnetic intermediate-layer coupling decreases due to a temperature increase, for example, the anti-ferromagnetic component increases, relatively speaking, and reduces the entire magnetic stray field of the layer arrangement in this way. Because of the temperature increase, the working point set previously is shifted to smaller magnetic fields in a corresponding manner, thereby compensating for a change in the sensitivity of the magneto-resistive layer stack as a function of the temperature. On the whole, this makes it possible to vary the change in the magnetic stray field or bias magnetic field with the temperature via the strength of the intermediate layer exchange coupling, which is a material constant and thus is determined via the selected materials, as well as via the layer thicknesses of the first magnetic layer and the second magnetic layer.

If the strength of the resulting magnetic field generated by the layer arrangement corresponds to a magnetic-field value required to achieve maximum sensitivity of the magneto-resistive layer stack, an especially high sensitivity of the magneto-resistive layer system or the sensor element produced thereby is advantageously achieved. In an advantageous manner, this sensitivity remains unchanged across the entire temperature interval to which the layer system is usually exposed during operation, i.e., the temperature interval from −30° C. to +200° C., for instance.

In the case of a magneto-resistive layer system on the basis of the GMR effect according to the coupled multilayer principle or the spin valve principle, having a third magnetic layer and a fourth magnetic layer, which are separated from one another by a second, non-magnetic intermediate layer and which jointly form the magneto-resistive layer stack, it is particularly advantageous if the magneto-resistive layer stack and the stack arrangement have a similar or, preferably, an identical temperature progression, which is especially easy to achieve if the same material is used for the second, non-magnetic intermediate layer and the non-magnetic intermediate layer of the layer arrangement. In this way, the layer arrangement and the magneto-resistive layer stack have a similar or identical temperature dependency, which is determined by the intermediate-layer exchange coupling in each case.

Moreover, it is advantageous that in various designs the layer arrangement is able to be brought close to the magneto-resistive layer stack, i.e., in a vertical integration, it may be arranged above or underneath the magneto-resistive layer stack, and/or, in a horizontal integration, it may be arranged on one side or preferably on both sides next to the magneto-resistive layer stack.

Finally, it is advantageous in general if the two magnetic layers of the layer arrangement have different thicknesses.

### BRIEF DESCRIPTION OF THE DRAWING

FIG. 1 shows a section through a magneto-resistive layer system.

### DETAILED DESCRIPTION

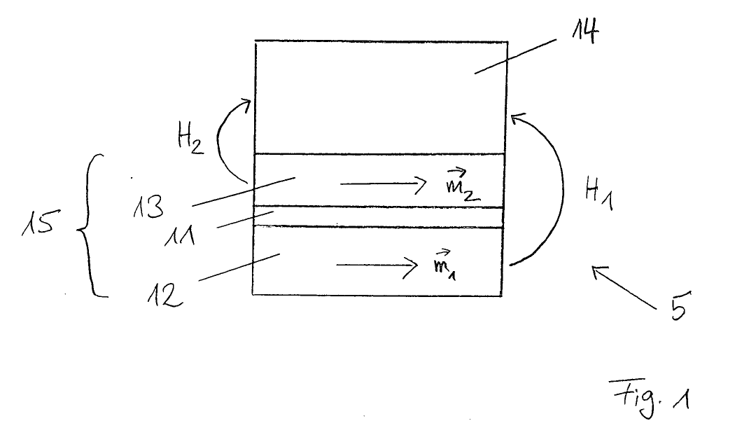

FIG. 1 shows a first magnetic layer 12 with a resulting magnetization m₁, having the direction indicated in FIG. 1, on which an intermediate layer 11 is situated. A second magnetic layer 13 with a resulting magnetization m_{z} having the direction indicated in FIG. 1 is arranged on intermediate layer 11. Positioned on second magnetic layer 13 is a magneto-resistive layer stack 14 as it is known per se from the related art. In particular, magneto-resistive layer stack 14 works on the basis of the GMR effect according to the coupled multilayer principle or according to the spin valve principle. First magnetic layer 12, intermediate layer 11 and second magnetic layer 13 jointly form a layer arrangement 15, which generates a resulting magnetic field that acts on the magneto-resistive layer stack. Furthermore, it is provided that first magnetic layer 12 and second magnetic layer 13 be ferromagnetically exchange-coupled via intermediate layer 11.

First magnetic layer 12 is, for instance, a magnetically soft layer, especially a layer from permalloy, CoFe, Co, Fe, Ni, FeNi as well as magnetic alloys containing these materials. Second magnetic layer 13 is, for instance, a magnetically hard layer, in particular one made from CoSm, CoCrPt, CoCrTa, Cr or CoPt. As an alternative, first magnetic layer 12 may also be a magnetically hard layer made of the mentioned materials, and second magnetic layer 13 may be a magnetically soft layer made of the mentioned materials. In addition, both first magnetic layer 12 and second magnetic layer 13 may be a magnetically hard layer made of CoSm, CoCrPt, CoCrTa, Cr or CoPt.

The thickness of first magnetic layer 12 differs from the thickness of second magnetic layer 13. The thickness of second magnetic layer 13 is preferably greater than that of first magnetic layer 12.

Non-magnetic intermediate layer 11 is made of, for example, copper, an alloy of, or containing, copper, silver and gold such as CuAgAu, or preferably made of ruthenium.

In the elucidated example according to FIG. 1, layer arrangement 15 is disposed underneath layer stack 14. However, it may just as well be arranged on top of or to the side of it.

Each first and/or second magnetic layer 12, 13 according to FIG. 1 has a thickness of between 10 nm and 100 nm, in particular between 20 nm and 50 nm. The thickness of intermediate layer 11 is selected in such a way that first magnetic layer 12 and second magnetic layer 13 are ferromagnetically exchange-coupled. It amounts to 0.8 nm, for instance.

The deposition of the individual layers discussed in FIG. 1 happens to be non-critical with respect to known influence factors. In particular the desired ferromagnetic intermediate layer exchange coupling may be adjusted with the aid of non-magnetic intermediate layer 11 via known layer thicknesses of intermediate layer 11.

Temperature fluctuations to which magneto-resistive layer system 5 according to FIG. 1 is exposed during operation, for instance in a sensor element for detecting external magnetic fields with respect to strength and/or direction, especially in a motor vehicle, are usually in the range of −30° C. to +200° C.

When the temperature rises, for instance based on the room temperature, a “softening” of the ferromagnetic intermediate layer exchange coupling initially occurs between first magnetic layer 12 and second magnetic layer 13. Simultaneously, the stray-field coupling of the two coupled magnetic layers 12, 13 of the ferromagnetic intermediate layer exchange coupling is directed oppositely. In this respect, this softening of the ferromagnetic layer coupling due to a rise in temperature, relatively speaking, leads to an increase in the oppositely directed stray-field coupling of magnetic layers 12, 13, so that the entire stray field of layer arrangement 15, i.e., the resulting magnetic field acting on magneto-resistive layer stack 14, decreases. The operating point of magneto-resistive layer stack 14, adjusted via layer arrangement 15, is shifted to smaller magnetic fields in a corresponding manner.

In this context, FIG. 1 indicates how first magnetic layer 12 generates a stray field H₁, which acts on magneto-resistive layer stack 14, and how second magnetic layer 13 generates a stray field H₂, which likewise acts on magneto-resistive layer stack 14.

In a softening of the intermediate layer exchange coupling between first magnetic layer 12 and second magnetic layer 13, the sum of stray fields H₁, H₂, i.e., the resulting bias magnetic field acting on the magneto-resistive layer stack, is reduced overall in the elucidated example.

If one of magnetic layers 12, 13 is a magnetically soft layer, such as second magnetic layer 13, it is even possible to adjust both stray fields H₁ and H₂ in such a way that they largely compensate each other.

Finally, it should also be mentioned that the elucidated concept for layer arrangement 15 may easily be integrated in existing magneto-resistive layer systems having GMR multilayers, GMR spin-valve configuration, and AMR layer systems such as CMR layer systems (colossal magneto-resistance). Moreover, it should be mentioned that magneto-resistive layer system 5 according to FIG. 1 is typically located on a substrate and connected to this substrate via a so-called buffer layer. Furthermore, a cover layer, for instance made of tantalum, may be situated on magneto-resistive layer stack 14 as well.

1-10. (canceled)

11. A magneto-resistive layer system comprising:
a magneto-resistive layer stack; and
at least one layer arrangement situated in an environment of the magneto-resistive layer stack working on the basis of one of a GMR effect and an AMR effect, which generates a resulting magnetic field acting upon the magneto-resistive layer stack, the layer arrangement including a first magnetic layer, a second magnetic layer, and a non-magnetic intermediate layer separating the first magnetic layer and the second magnetic layer from one another, the first magnetic layer and the second magnetic layer being ferromagnetically exchange-coupled via the intermediate layer.

12. The magneto-resistive layer system according to claim 11, wherein one of: (a) the first magnetic layer is a magnetically soft layer, made of permalloy, CoFe, Co, Fe, Ni, FeNi as well as magnetic alloys containing these materials, and the second magnetic layer is a magnetically hard layer, made of one of CoSm, CoCrPt, CoCrTa, Cr and CoPt, and (b) the first magnetic layer is a magnetically hard layer, made of one of CoSm, CoCrPt, CoCrTa, Cr and CoPt, and the second magnetic layer is a magnetically soft layer, made of permalloy, CoFe, Co, Fe, Ni, FeNi, as well as magnetic alloys containing these materials.

13. The magneto-resistive layer system according to claim 11, wherein each of the first magnetic layer and the second magnetic layer is a magnetically hard layer, made of one of CoSm, CoCrPt, CoCrTa, Cr and CoPt.

14. The magneto-resistive layer system according to claim 11, wherein the first magnetic layer has a different thickness than the second magnetic layer.

15. The magneto-resistive layer system according to claim 11, wherein the layer stack has a third magnetic layer and a fourth magnetic layer which are separated from one another by a second non-magnetic intermediate layer, and the non-magnetic intermediate layer of the layer arrangement and the second non-magnetic intermediate layer of the layer stack at least one of (a) are at least substantially made of the same material and (b) have a substantially equal thickness.

16. The magneto-resistive layer system according to claim 11, wherein the non-magnetic intermediate layer is made of at least one of (a) copper, (b) and alloy one of including and made of copper, (c) silver and gold, and (d) ruthenium.

17. The magneto-resistive layer system according to claim 11, wherein the layer arrangement is situated at least one of (a) on top of, (b) underneath and (c) next to the layer stack.

18. The magneto-resistive layer system according to claim 11, wherein at least one of the first magnetic layer and the second magnetic layer has a thickness between 10 nm and 100 nm.

19. The magneto-resistive layer system according to claim 18, wherein the thickness is between 20 nm and 50 nm.

20. The magneto-resistive layer system according to claim 11, wherein, in response to a change in a temperature to which the magneto-resistive layer system is exposed, one of a changing sensitivity and a shifting working point of the magneto-resistive layer stack with respect to an external magnetic field to be measured with respect to at least one of strength and direction, is at least partially compensated within a predefined temperature interval by the resulting magnetic field generated by the layer arrangement, which also changes as a result of the temperature change.

21. The magneto-resistive layer system according to claim 20, wherein the compensation is performed completely and the temperature interval is −30° C. to +200° C.

22. A sensor element comprising a magneto-resistive layer system, the magneto-resistive layer system including:
a magneto-resistive layer stack; and
at least one layer arrangement situated in an environment of the magneto-resistive layer stack working on the basis of one of a GMR effect and an AMR effect, which generates a resulting magnetic field acting upon the magneto-resistive layer stack, the layer arrangement including a first magnetic layer, a second magnetic layer, and a non-magnetic intermediate layer separating the first magnetic layer and the second magnetic layer from one another, the first magnetic layer and the second magnetic layer being ferromagnetically exchange-coupled via the intermediate layer.

23. The sensor element according to claim 22, wherein the sensor element is for detecting magnetic fields with respect to at least one of strength and direction.
